(19) United States
(12) Patent Application Publication
(10) Pub. No.: US 2026/0082520 A1
(43) Pub. Date: Mar. 19, 2026

(54) HEAT DISSIPATION DEVICE AND SERVER

(71) Applicants: CHAMP TECH OPTICAL (FOSHAN) CORPORATION, Foshan (CN); HON HAI PRECISION INDUSTRY CO., LTD., New Taipei (TW)

(72) Inventors: PEI-JEN LIN, New Taipei (TW); Fu-Lin Yang, New Taipei (TW); Wen-Hsien Lin, New Taipei (TW)

(21) Appl. No.: 18/973,435

(22) Filed: Dec. 9, 2024

(30) Foreign Application Priority Data
Sep. 18, 2024 (CN) 202411304483.4

(51) Int. Cl. H05K 7/20

(52) U.S. Cl. CPC H05K 7/20772

(57) ABSTRACT

A heat dissipation device is provided for a server. The heat dissipation device comprises a plurality of first heat-conducting members, a plurality of second heat-conducting members and two liquid cooling members. Each of the plurality of second heat-conducting members is elastic deformable along the first direction, so that each of the slots squeezes a corresponding memory storage and the plurality of second heat-conducting members is closely in contact with the corresponding memory storage.

### FIELD

The present disclosure relates to the technical field of heat dissipation, in particular to a heat dissipation device and a server.

### BACKGROUND

Currently, a heat dissipation device is provided to dissipate heat from memory storages of server. However, heat dissipation devices are generally not effective.

### BRIEF DESCRIPTION OF THE DRAWINGS

In order to illustrate the technical solutions of the embodiments of the present application more clearly, the accompanying drawings in the embodiments will be briefly introduced below. It should be understood that the following drawings only show some embodiments of the present application, and therefore should not be seen as limiting the scope. For one of ordinary skill in the art, other related drawings can also be obtained from these drawings without any creative work.

Implementations of the present technology will now be described, by way of embodiments, with reference to the attached figures, wherein:

FIG. 1 shows a schematic structural view of a server in an embodiment of the present disclosure.

FIG. 2 shows a top view of a heat dissipation device in the server shown in FIG. 1.

FIG. 3 shows a partial structural sectional view of the heat dissipation device in the server shown in FIG. 1.

FIG. 4 shows a schematic diagram of a first heat-conducting member and a second heat-conducting member in the server shown in FIG. 1, in an assembled state.

FIG. 5 shows an exploded view of the first heat-conducting member and the second heat-conducting member in the server shown in FIG. 1.

FIG. 6 shows a cross-sectional view of the first heat-conducting member, the second heat-conducting member, and a memory storage in the server shown in FIG. 1, in a closed state.

FIG. 7 shows a cross-sectional view of the first heat-conducting member, the second heat-conducting member and the memory storage in a released state.

FIG. 8 shows a schematic diagram of the first heat-conducting member and the second heat-conducting member in the server shown in FIG. 1, in the assembled state.

FIG. 9 shows a schematic diagram of the first heat-conducting member, the second heat-conducting member and a constraining member of the server shown in FIG. 1, in the assembled state.

FIG. 10 shows a top view of a server in another embodiment of the present disclosure.

FIG. 11 shows a schematic diagram of the first heat-conducting member and the second heat-conducting member of the server shown in FIG. 10, in an assembled state.

FIG. 12 shows a cross-sectional view of the first heat-conducting member, the second heat-conducting member, the memory storage, and a plugging structure of the server in FIG. 10.

FIG. 13 shows a cross-sectional view of the first heat-conducting member, the second heat-conducting member and the memory storage of the server in FIG. 10.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. The drawings are not necessarily to scale, and the proportions of certain parts may be exaggerated to illustrate details and features better. The description is not to be considered as limiting the scope of the embodiments described herein.

Several definitions that apply throughout this disclosure will now be presented.

The term “substantially” is defined to be essentially conforming to the particular dimension, shape or other word that substantially modifies, such that the component need not be exact. For example, substantially cylindrical means that the object resembles a cylinder, but can have one or more deviations from a true cylinder. The term “comprising” means “including, but not necessarily limited to”; it specifically indicates open-ended inclusion or membership in a so-described combination, group, series and the like.

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

The technical solutions in the embodiments of the present application will be clearly and completely described below with reference to the accompanying drawings in the embodiments of the present application. Obviously, the described embodiments are only a part of the embodiments of the present application, but not all of the embodiments.

It should be noted that when an element is referred to as being “fixed to” another element, it can be directly on the other element or intervening elements may also be present. When an element is referred to as being “connected” to another element, it can be directly connected to the other element or intervening elements may also be present. When an element is referred to as being “disposed on” another element, it can be directly disposed on the other element or intervening elements may also be present. The terms “vertical” “horizontal” “left” “right” and similar expressions are used herein for illustrative purposes only.

Unless otherwise defined, all technical and scientific terms used herein have the same meaning as commonly understood by one of ordinary skill in the art. The terms used herein in the specification of the present application are for the purpose of describing particular embodiments only, and are not intended to limit the present application. As used herein, the term “or/and” includes any and all combinations of one or more of the associated listed items.

Some embodiments of the present application are described in detail. The following embodiments and features of the embodiments may be combined with each other without conflict.

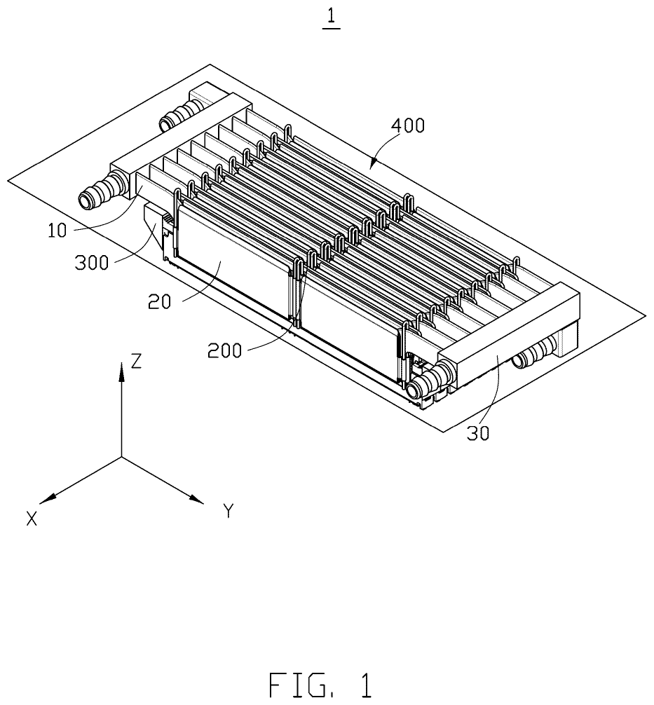

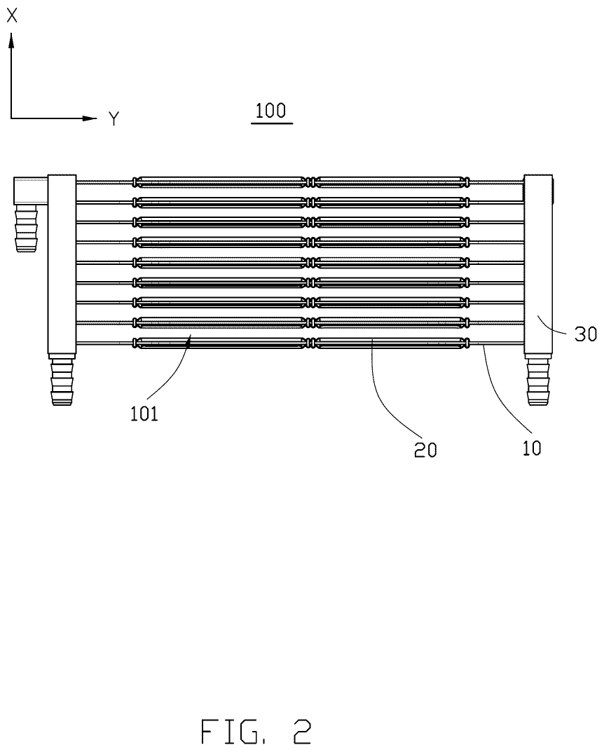

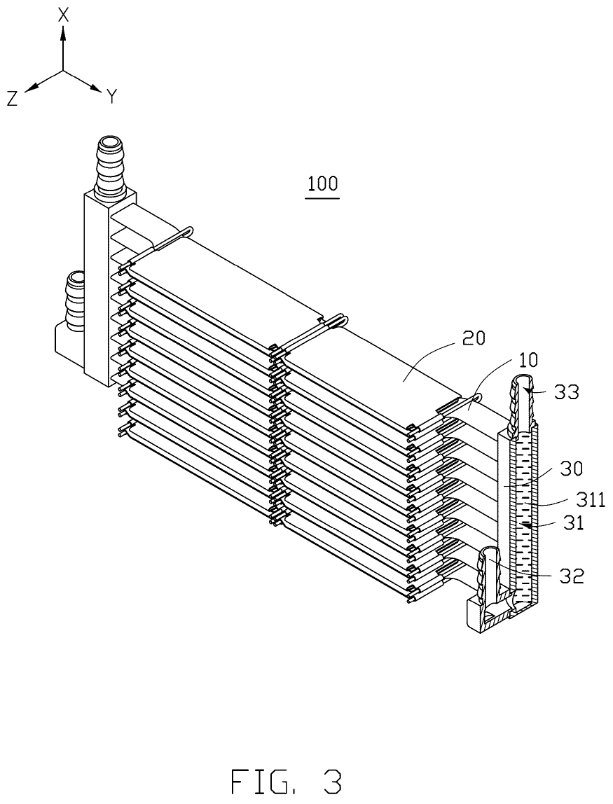

FIG. 1 shows a schematic structural view of a server 1 in an embodiment of the present disclosure. FIG. 2 shows a top view of a heat dissipation device 100 in the server 1 shown in FIG. 1. FIG. 3 shows a partial structural sectional view of the heat dissipation device 100 in the server 1 shown in FIG. 1.

Referring to FIGS. 1 and 2, an embodiment of the present disclosure provides a server 1 comprising a heat dissipation device 100 and a plurality of memory storages 200 200. The heat dissipation device 100 is used to dissipate heat from the plurality of memory storages 200 200.

The server 1 further comprises a plugging structure 300 and a circuit board 400, the plugging structure 300 is disposed on the circuit board 400, and the memory storages 200 200 is plugged into the plugging structure 300. The heat dissipation device 100 and the plugging structure 300 are arranged on the same side of the circuit board 400.

Referring to FIGS. 2 and 3, the heat dissipation device 100 comprises a plurality of first heat-conducting members 10, a plurality of second heat-conducting members 20, and two liquid cooling members 30.

The plurality of first heat-conducting members 10 are arranged at intervals along a first direction X. The plurality of second heat-conducting members 20 are arranged at intervals along the first direction X. The plurality of second heat-conducting members 20 correspond to the plurality of first heat-conducting members 10 in an one-to-one relationship. One of the plurality of the second heat-conducting members 20 is coupled with and attached to a corresponding first heat-conducting members 10 of the plurality of first heat-conducting members 10. Slots 101 are defined between each of two adjacent of the plurality of second heat-conducting members 20 along the first direction X. Each of the slots 101 are configured for receiving a memory storage 200 therein. Each of the plurality of second heat-conducting members 20 is configured to be capable of elastic deformation along the first direction X, so that each of the memory storages 200 200 is able to be squeezed into corresponding the slot 101 and contacted to the second heat-conducting members 20 closely. The two liquid cooling members 30 are respectively located at and connected to two ends of the plurality of first heat-conducting members 10 along a second direction Y. The plurality of first heat-conducting members 10 extends along the direction Y. The second direction Y is perpendicular to the first direction X. The liquid cooling member 30 is provided with a flow channel 31 configured for accommodating receiving a cooling medium 311 therein. Two ends of the first heat-conducting member 10 along the second direction Y are connected to the two liquid cooling members 30 respectively to transfer the heat generated by the memory storages 200 200 to the liquid cooling members 30 and the cooling medium 311.

Since the second heat-conducting member 20 is able to be elastic deformed along the first direction X, so that after the memory storage 200 is received into the slot 101, the memory storage 200 is able to be closely contacted to the second heat-conducting member 20, thereby lowering the contact thermal resistance between the memory storage 200 and the second heat-conducting member 20, improving the heat transfer efficiency, and thereby increasing the heat dissipation effect on the memory storage 200. When in use, the heat generated by the memory storages 200 200 is transferred to the second heat-conducting member 20, and then the heat is transferred to the first heat-conducting member 10 through the second heat-conducting member 20, and the first heat-conducting member 10 transfers the heat to the two liquid cooling members 30 respectively, so as to take away the heat of the liquid cooling members 30 through the cooling medium 311, and to achieve the purpose of heat dissipation. And the memory storage 200 is easily inserted into the slot 101 because the second heat-conducting member 20 is able to elastically deform along the first direction X.

By arranging the plurality of second heat-conducting members 20 spaced apart along the first direction X, the slots 101 are formed spaced apart along the first direction X. The slots 101 may be used for receiving the memory storages 200 200 one by one. By connecting two ends of the first heat-conducting member 10 to the liquid cooling member 30 respectively, the heat of the first heat-conducting member 10 may be transferred to the liquid cooling member 30 without cooling medium flowing through the first heat-conducting member 10, i.e., there is no need to set up a channel for the cooling medium 311 to flow through the first heat-conducting member 10. Thus, it is favorable to reduce the thickness of the first heat-conducting member 10 along the first direction X. Optionally, the material of the liquid cooling member 30 may be a metal with a high heat transfer coefficient, such as copper or aluminum. The first heat-conducting member 10 is welded to the liquid cooling member 30.

Optionally, the first heat-conducting member 10 may be a heat pipe, a vapor chamber, or a heat dissipation fin. When the first heat-conducting member 10 is a heat dissipation fin, the material of the first heat-conducting member 10 may be metal.

In some embodiments, as shown in FIG. 3, the liquid cooling member 30 is provided with an inlet 32 and an outlet 33. The inlet 32 and the outlet 33 are communicated to two ends of the flow channel 31, respectively, so that the cooling medium 311 may flow into the flow channel 31 through the inlet 32 and out of the flow channel 31 through the outlet 33. Optionally, as shown in FIG. 3, the flow channel 31 extends along the first direction X.

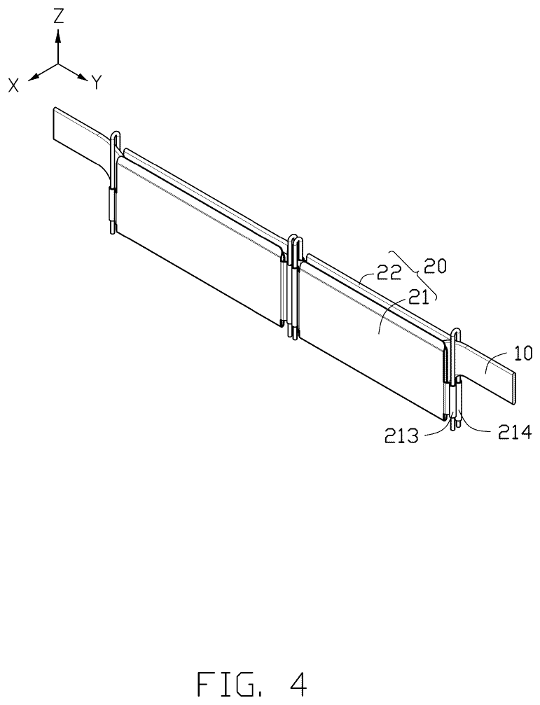

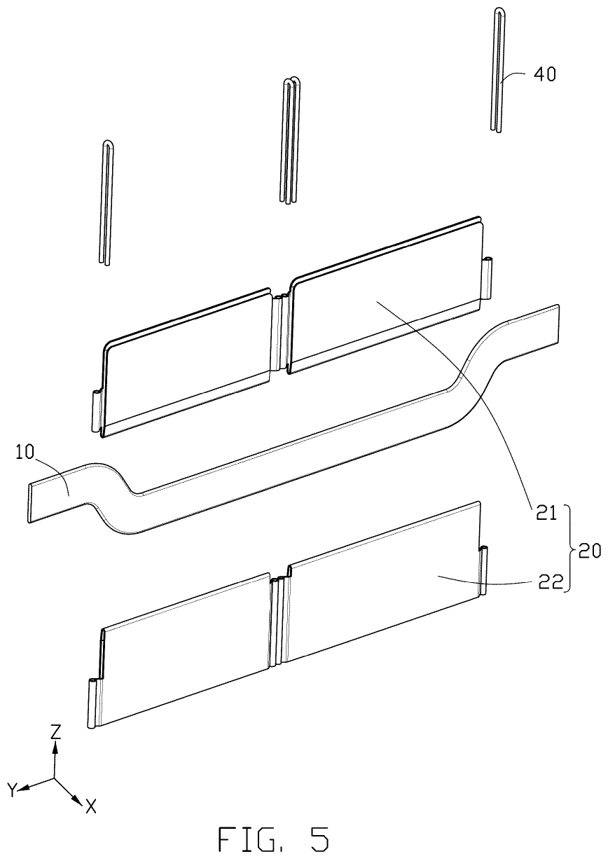

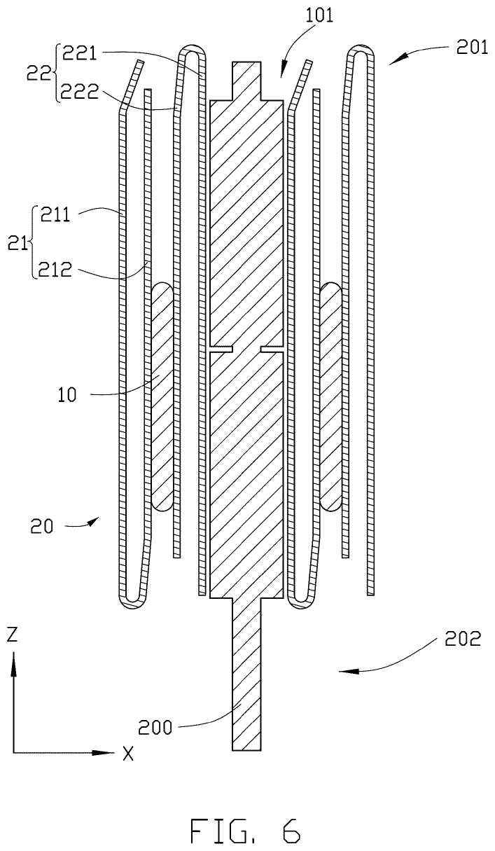

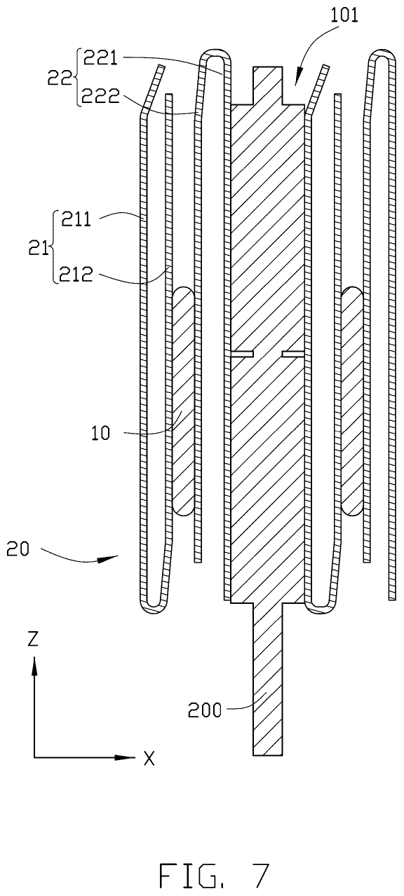

FIG. 4 shows a schematic diagram of a first heat-conducting member 10 and a second heat-conducting member 20 in the server 1 shown in FIG. 1, in an assembled state. FIG. 5 shows an exploded view of the first heat-conducting member 10 and the second heat-conducting member 20 in the server 1 shown in FIG. 1. FIG. 6 shows a cross-sectional view of the first heat-conducting member 10, the second heat-conducting member 20, and a memory storage 200 in the server 1 shown in FIG. 1, in a closed state. FIG. 7 shows a cross-sectional view of the first heat-conducting member 10, the second heat-conducting member 20 and the memory storage 200 in a released state.

In some embodiments, as shown in FIGS. 4 and 5, each of the plurality of second heat-conducting members 20 comprises a first metal spring tab 21 and a second metal spring tab 22. The first metal spring tab 21 and the second metal spring tab 22 are attached to opposite sides of the first heat-conducting member 10 along the first direction X. As shown in FIG. 6, the first metal spring tab 21 comprises a first contacting portion 211 and a first connecting portion 212. The first connecting portion 212 is bent and connected to an end of the first contacting portion 211 along a third direction Z. The first connecting portion 212 is opposite to the first contacting portion 211 along the first direction X. The first connecting portion 212 is located at a side of the first contacting portion 211 close to the corresponding first heat-conducting member 10. The third direction Z is perpendicular to the first direction X and the second direction Y. The first direction X, the second direction Y, and third direction Z form a spatial Cartesian coordinate system. The second metal spring tab 22 comprises a second contacting portion 221 and a second connecting portion 222. The second connecting portion 222 is bent and connected to an end of the second contacting portion 221 along the third direction Z. The second connecting portion 222 is opposite to the second contacting portion 221 along the first direction X, and the second connecting portion 222 is located at an side of the second contacting portion 221 close to the corresponding first heat-conducting member 10. Each of the plurality of first heat-conducting members 10 is connected between the first connecting portion 212 and the second connecting portion 222 near to the first connecting portion 212. Each of the slots 101 is defined between the first contacting portion 211 and the second contacting portion 221 near to the first connecting portion 212.

When the memory storage 200 is received in the slot 101, the heat generated by the memory storage 200 may be transferred from a side of the memory storage 200 along the first direction X to the first contacting portion 211, and then through the first contacting portion 211 to the first connecting portion 212, so as to transfer the heat to the first heat-conducting member 10 through the first connecting portion 212. The heat generated by the memory storage 200 may also be transferred from a side of the memory storage 200 along the first direction X away from the side of the first contacting portion 211 to the second contacting portion 221, which in turn passes through the second contacting portion 221 to the second connecting portion 222, thereby transferring the heat through the second connecting portion 222 to the first heat-conducting member 10, and the first heat-conducting member 10 transfers the heat to the liquid cooling member 30.

It should be understood that, the first contacting portion 211 and the first connecting portion 212 can move towards or away from each other along the first direction X, so that the first metal spring tab 21 is capable of undergoing elastic deformation along the first direction X. And the second contacting portion 221 and the second connecting portion 222 can move towards or away from each other along the first direction X, so that the second metal spring tab 22 is capable of undergoing elastic deformation along the first direction X. The second heat-conducting member 20 has a closed state and a released state. As shown in FIG. 6, in the closed state, when the memory storage 200 is received in the slot 101, the first contacting portion 211 has a gap between the first contacting portion 211 and the memory storage 200 along the first direction X, and the second contacting portion 221 has a gap between the second contacting portion 221 and the memory storage 200 along the first direction X, so as to facilitate insertion the memory storage 200 into the slot 101, or removal of the memory storage 200 from the slot 101. As shown in FIG. 7, in the released state, the first contacting portion 211 is tightly fit to one side of the memory storage 200 along the first direction X, and the second contacting portion 221 is tightly fit to the other side of the memory storage 200 along the first direction X to dissipate heat from the memory storage 200.

Optionally, the first connecting portion 212 is welded to one side of the first heat-conducting member 10 along the first direction X. The second connecting portion 222 is welded to the other side of the first heat-conducting member 10 along the first direction X. It favors the first connecting portion 212 and the second connecting portion 222 to transfer heat to the first heat-conducting member 10, respectively. And it makes the first connecting portion 212 and the second connecting portion 222 fixedly connected to the first heat-conducting member 10, respectively.

In some embodiments, as shown in FIG. 6, each of the plurality of second heat-conducting members 20 has a top side 201 and a bottom side 202 opposite to the top side 201 along the third direction Z. The first connecting portion 212 is bent and connected to an end of the first contacting portion 211 along the third direction Z near to the bottom side 202. The second connecting portion 222 is bent and connected to an end of the second contacting portion 221 along the third direction Z near to the top side 201, so that the elastic deformation amount of the second heat-conducting member 20 may be distributed more evenly in the third direction Z, so that the memory storage 200 may be more easily inserted into the slot 101, and the first contacting portion 211 and the second contacting portion 221 may be more tightly contacted to the memory storage 200.

In some embodiments, as shown in FIG. 6, the first contacting portion 211 is capable of covering a side of the memory storage 200 along the first direction X to increase a contact area between the first contacting portion 211 and the memory storage 200, and to improve a heat transfer efficiency between the memory storage 200 and the first contacting portion 211. The second contacting portion 221 can cover a side of the memory storage 200 along the first direction X away from the first contacting portion 211 to increase a contact area between the second contacting portion 221 and the memory storage 200, and improve the heat transfer efficiency between the memory storage 200 and the second contacting portion 221. Optionally, along the third direction Z, the first heat-conducting member 10 covers a portion of the first connecting portion 212, and the first heat-conducting member 10 covers a portion of the second connecting portion 222 to provide a space between the portion of the first connecting portion 212 and the portion of the second connecting portion 222 along the first direction X to facilitate an elastic deformation of the first metal spring tab 21 and the second metal spring tab 22 respectively along the first direction X.

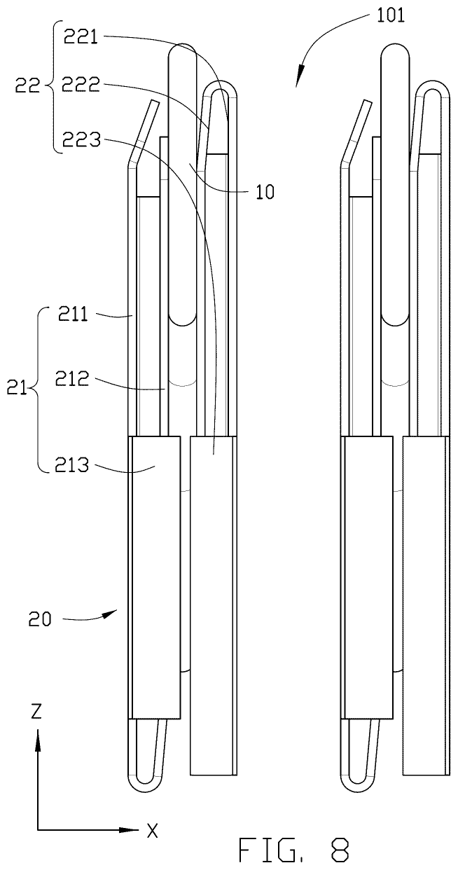

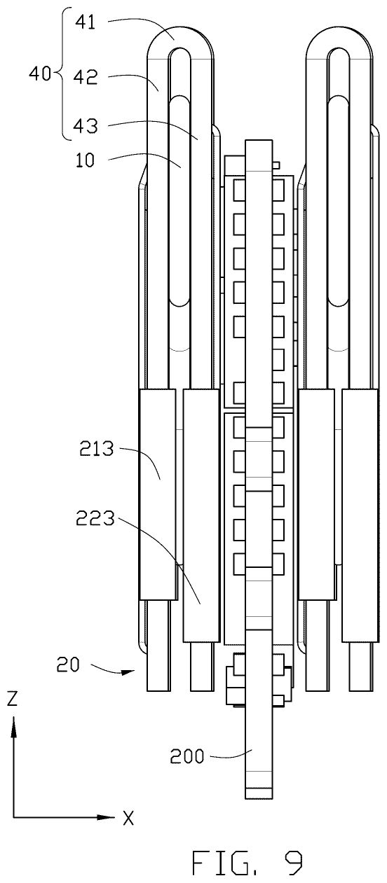

FIG. 8 shows a schematic diagram of the first heat-conducting member 10 and the second heat-conducting member 20 in the server 1 shown in FIG. 1, in the assembled state. FIG. 9 shows a schematic diagram of the first heat-conducting member 10, the second heat-conducting member 20 and a constraining member 40 of the server 1 shown in FIG. 1, in the assembled state.

In some embodiments, as shown in FIG. 8, the first contacting portion 211 is provided with a first sleeve 213. The first sleeve 213 has an axial direction parallel to the third direction Z. The second contacting portion 221 is provided with a second sleeve 223. The second sleeve 223 corresponds to the first sleeve 213. The second sleeve 223 has an axial direction parallel to the third direction Z. As shown in conjunction with FIG. 9, the heat dissipation device 100 further includes a constraining member 40, the constraining member 40 corresponds to the first sleeve 213 and the second sleeve 223, respectively, and the constraining member 40 is movably disposed along the third direction Z to be threaded through the corresponding first sleeve 213 and second sleeve 223, respectively, so as to cause the first contacting portion 211 to be brought together toward the first connecting portion 212, and to cause the second contacting portion 221 to be brought toward the second connecting portion 222. So that, it is possible to switch the second heat-conducting member 20 from the released state to the closed state by threading the constraining member 40 into the first sleeve 213 and the second sleeve 223, respectively, so that the thickness of the second heat-conducting member 20 along the first direction X is reduced to facilitate the insertion and removal of the memory storage 200 into and out of the slot 101. And it is possible to switch the second heat-conducting member 20 from the closed state to the released state by pulling the constraining member 40 out of the first sleeve 213 and the second sleeve 223, so that the thickness of the second heat-conducting member 20 along the first direction X is increased, thereby closely fitting with the memory storage 200 and enhancing the heat dissipation effect. Thus, by providing the constraining member 40, the second heat-conducting member 20 is more easily switched between the closed state and the released state for easy operation.

When in use, when the memory storage 200 needs to be installed in the slot 101, at first, the constraining member 40 is inserted into the first sleeve 213 and the second sleeve 223 along the third direction Z, and then the memory storage 200 is inserted into the slot 101 along the third direction Z. The constraining member 40 is then taken out of the first sleeve 213 and the second sleeve 223 along the third direction Z, so that the second heat-conducting member 20 is in close contact with the memory storage 200.

In some embodiments, as shown in FIGS. 8 and 9, the second sleeve 223 and the corresponding first sleeve 213 are spaced apart from each other and disposed opposite each other along the first direction X. The constraining member 40 comprises a bending portion 41, a first plunger 42, and a second plunger 43. An end of the first plunger 42 is connected to an end of the bending portion 41, the first plunger 42 extends in a third direction Z, and the first plunger 42 is movably disposed through the first sleeve 213 along the third direction Z. An end of the second plunger 43 is connected to an end of the bending portion 41 that is away from the first plunger 42, the second plunger 43 extends along the third direction Z, the second plunger 43 is spaced apart from and disposed opposite the first plunger 42 along the first direction X, and the second plunger 43 is movably disposed through the second sleeve 223 along the third direction Z. In this way, by inserting the first plunger 42 into the first sleeve 213 and inserting the second plunger 43 into the second sleeve 223, the distance between the first sleeve 213 and the second sleeve 223 along the first direction X is reduced, thereby decreasing the distance between the first contacting portion 211 and the second contacting portion 221 of the same second heat-conducting member 20 along the first direction X, and thereby increasing the distance between two adjacent second contacting portions 221 for insertion of the memory storage 200. The first sleeve 213 and the second sleeve 223 are provided opposite each other and spaced apart along the first direction X, and the first plunger 42 and the second plunger 43 are provided opposite each other and spaced apart along the first direction X, so as to facilitate alignment of the first plunger 42 and the second plunger 43 with the first sleeve 213 and the second sleeve 223, respectively, to facilitate the mounting of the constraining member 40.

In some embodiments, as shown in FIG. 4, each first contacting portion 211 (see FIG. 8) is provided with a first sleeve 213 at each end of the first contacting portion 211 along the second direction Y, and the second contacting portion 221 is provided with a second sleeve 223 at each end of the second contacting portion 221 along the second direction Y, such that both ends of the first contacting portion 211 along the second direction Y are able to be subjected to constraining action by the constraining member 40 respectively, and both ends of the second contacting portion 211 along the second direction Y are able to be subjected to constraining action by the constraining member 40 respectively, so as to make it easier for the memory storage 200 to be inserted into the slot 101.

In some embodiments, as shown in FIGS. 4 and 5, each first heat-conducting member 10 corresponds to a plurality of second heat-conducting members 20, and the plurality of second heat-conducting members 20 corresponding to a same first heat-conducting member 10 are arrayed along the second direction Y, which reduces the size of the second heat-conducting members 20 along the second direction Y, so as to increase the constraining effect of the constraining member 40 on the second heat-conducting members 20, and making the elasticity of the second heat-conducting members 20 deformation along the second direction Y is more evenly distributed so as to facilitate insertion of the memory storage 200 into the slot 101 (see FIG. 6). In this embodiment, each first heat-conducting member 10 corresponds to two second heat-conducting members 20.

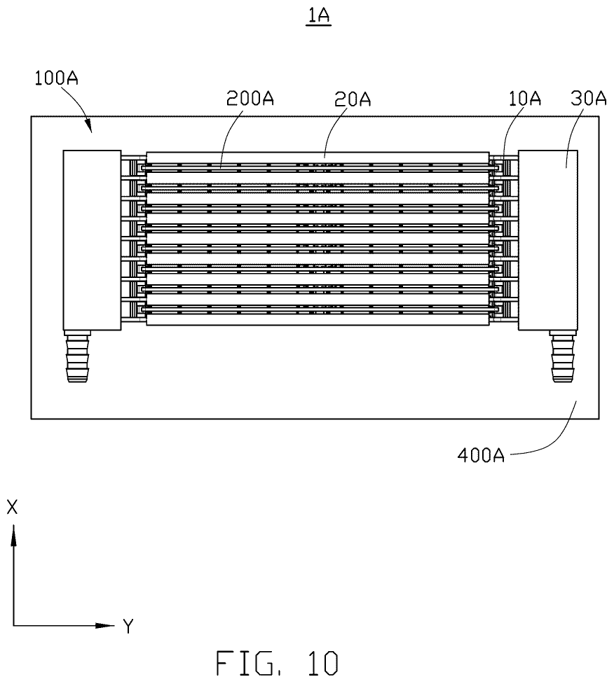

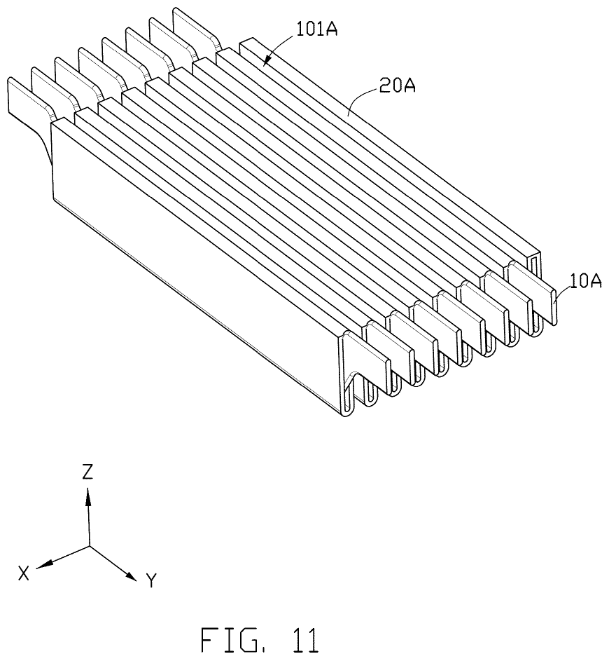

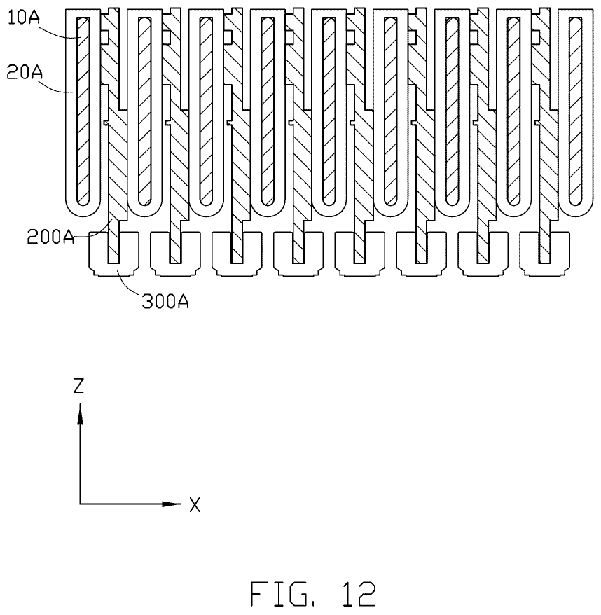

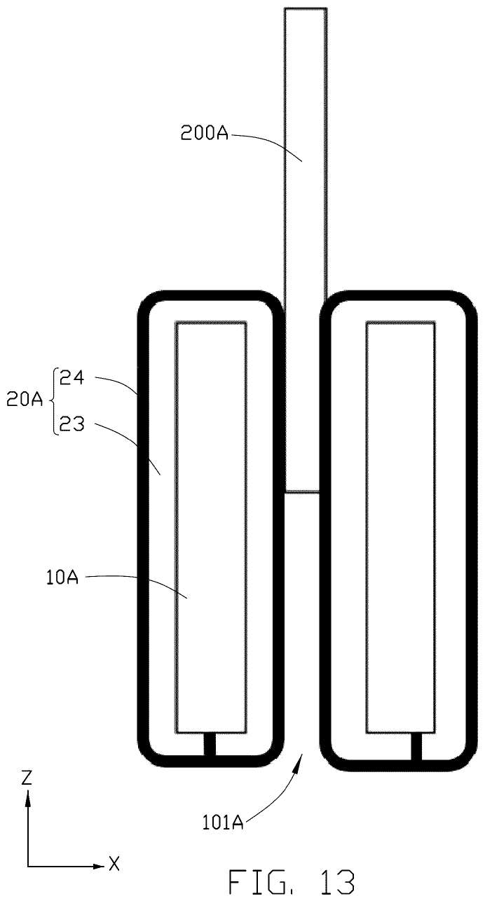

FIG. 10 shows a top view of a server 1A in another embodiment of the present disclosure. FIG. 11 shows a schematic diagram of the first heat-conducting member 10A and the second heat-conducting member 20A of the server 1A shown in FIG. 10, in an assembled state. FIG. 12 shows a cross-sectional view of the first heat-conducting member 10A, the second heat-conducting member 20A, the memory storage 200A, and a plugging structure 300A of the server 1A in FIG. 10. FIG. 13 shows a cross-sectional view of the first heat-conducting member 10A, the second heat-conducting member 20A and the memory storage 200A of the server 1A in FIG. 10.

Referring to FIGS. 10 to 12, the server 1A is substantially the same as the server 1, with the difference that, as shown in FIG. 13, the second heat-conducting member 20A of the heat dissipation device 100A comprises a thermal interface material 23. The thermal interface material 23 is elastic, and the thermal interface material 23 is disposed on the opposing sides of the first heat-conducting member 10A along the first direction X. In this way, the elastic deformation of the thermal interface material 23 along the first direction X enables the memory storage 200A to squeeze the thermal interface material 23 so as to be inserted into the slot 101A. And when the memory storage 200A is received in the slot 101A, the second heat-conducting member 20A is closely contacted to the memory storage 200A due to the tendency of the thermal interface material 23 to rebound towards the side far away from the first heat-conducting member 10A along the first direction X, which in turn improves the heat dissipation effect of the memory storage 200A.

Optionally, the thermal interface material 23 may be a thermal spacer, a thermally conductive adhesive, a silicone gel, or a silicone grease, etc., as long as the thermal interface material 23 is a flexible material, which is not limited herein.

In some embodiments, as shown in FIGS. 12 and 13, the first heat-conducting member 10A extends from one end of the memory storage 200A along the third direction Z to the other end of the memory storage 200A. The second heat-conducting member 20A covers a portion of the first heat-conducting member 10A opposite to the memory storage 200A along the first direction X, so as to increase a contact area of the second heat-conducting member 20A with the first heat-conducting member 10A, and to increase a contact area of the second heat-conducting member 20A with the memory storage 200A, thereby increasing the heat transfer efficiency. In this embodiment, the second heat-conducting member 20A is socketed outside the portion of the first heat-conducting member 10A opposite to the memory storage 200A along the first direction X.

In some embodiments, as shown in FIG. 13, each of the plurality of second heat-conducting members 20A further comprises a thermally conducting film 24. The thermally conducting film 24 is wrapped on a side of the thermal interface material 23 away from each of the plurality of first heat-conducting members 10A, and each of the slots 101A is between each two adjacent thermally conducting films 24 of the thermally conducting films 24. In this way, by providing the thermally conducting film 24 24 to provide a protective and positioning effect on the thermal interface material 23, to avoid direct contact between the memory storage 200A and the thermal interface material 23 when the memory storage 200A is received in the slots 101A, and therefore avoiding breakage or deflection of the thermal interface material 23. In use, the heat generated by the memory storage 200A is transferred to the thermally conducting film 24, and then the heat is transferred from the thermally conducting film 24 to the thermal interface material 23, and then the heat is transferred from the thermal interface material 23 to the first heat-conducting member 10A, and at last, the heat is transferred from the first heat-conducting member 10A to the liquid cooling member 30A (see FIG. 10).

Optionally, the thermally conducting film 24 may be a plastic film, so that the thermally conducting film 24 has better heat-conducting properties and abrasion resistance. For example, the thermally conducting film 24 may be a polyimide film (PI film).

The above embodiments are only used to illustrate the technical solution of the application rather than for limitation. Although the application is described in detail with reference to the above preferred embodiments, those skilled in the art should understand that any modification or equivalent replacement of the technical solution of the application should not deviate from the spirit and scope of the technical solution of the application.

The above embodiments are only used to illustrate the technical solutions of the present application rather than limitations. Although the present application has been described in detail with reference to the above preferred embodiments, one of ordinary skill in the art should understand that the technical solutions of the present application may be modified or equivalently replaced without departing from the spirit and scope of the technical solutions of the present application.

What is claimed is:

1. A heat dissipation device in a server having a plurality of memory storages, the heat dissipation device comprising:
a plurality of first heat-conducting members arranged at intervals along a first direction;
a plurality of second heat-conducting members arranged at intervals along the first direction, the plurality of second heat-conducting members corresponds to the plurality of first heat-conducting members in an one-to-one relationship, each of the plurality of second heat-conducting members is respectively attached to a corresponding first heat-conducting member of the plurality of first heat-conducting members, along opposite two sides of the corresponding first heat-conducting member in the first direction, slots are defined between each of two of the plurality of second heat-conducting members along the first direction, each of the slots is configured for [symbol] mounting a memory storage of the plurality of memory storages of the server, each of the plurality of second heat-conducting members is elastic deformable along the first direction, so that each of the slots squeezes a corresponding memory storage and the plurality of second heat-conducting members is closely in contact with the corresponding memory storage; and,
two liquid cooling members respectively located at and connected to two ends of the plurality of first heat-conducting members along a second direction, the liquid cooling members are provided with a flow channel configured for accommodating a cooling medium, wherein the second direction is perpendicular to the first direction;
wherein heat generated by the plurality of memory storages is transferred to the two liquid cooling members and the cooling medium at the two ends of the plurality of first heat-conducting members.

2. The heat dissipation device of claim 1, wherein each of the plurality of second heat-conducting members further comprises a first metal spring tab and a second metal spring tab, the first metal spring tab and the second metal spring tab are located, along the first direction, on respective sides of the corresponding first heat-conducting members;
the first metal spring tab comprises a first contacting portion and a first connecting portion, the first connecting portion is bent and connected to an end of the first contacting portion along a third direction, and the first connecting portion is opposite to the first contacting portion along the first direction, the first connecting portion is located at an side of the first contacting portion close to the corresponding first heat-conducting member, the third direction is perpendicular to the first direction and the second direction respectively;
the second metal spring tab comprises a second contacting portion and a second connecting portion, the second connecting portion is bent and connected to an end of the second contacting portion along the third direction, the second connecting portion is opposite to the second contacting portion along the first direction, and the second connecting portion is located at an side of the second contacting portion close to the corresponding first heat-conducting member;
each of the plurality of first heat-conducting members is connected between the first connecting portion and the second connecting portion near to the first connecting portion;
each of the slots is defined between the first contacting portion and the second contacting portion near the first connecting portion.

3. The heat dissipation device of claim 2, wherein each of the plurality of second heat-conducting members comprises a top side and a bottom side opposite to the top side along the third direction;
the first connecting portion is bent and connected to an end of the first contacting portion along the third direction close to the bottom side;
the second connecting portion is bent and connected to an end of the second contacting portion along the third direction close to the top side.

4. The heat dissipation device of claim 2, wherein the first contacting portion is provided with a first sleeve, and an axial direction of the first sleeve is parallel to the third direction;
the second contacting portion is provided with a second sleeve, the second sleeve corresponds to the first sleeve, and an axial direction of the second sleeve is parallel to the third direction;
the heat dissipation device further comprises a constraining member, the constraining member corresponds to the first sleeve and the second sleeve respectively, and the constraining member is movably mounted to the first sleeve and the second sleeve along the third direction, so that the first contacting portion is closed towards the first connecting portion, and the second contacting portion is closed toward the second connecting portion.

5. The heat dissipation device of claim 4, wherein the second sleeve and the first sleeve are spaced apart from each other along the first direction;
the constraining member comprises a bending portion, a first plunger and a second plunger;
an end of the first plunger is connected with an end of the bending portion, the first plunger extends along the third direction, and the first plunger is movably mounted to the first sleeve along the third direction;
an end of the second plunger is connected with an end of the bending portion away from the first plunger, the second plunger extends along the third direction, the second plunger is spaced from the first plunger along the first direction, and the second plunger is movably mounted to the second sleeve along the third direction.

6. The heat dissipation device of claim 5, wherein two ends along the second direction of the first contacting portion are respectively provided with the first sleeve;
two ends along the second direction of the second contacting portion are respectively provided with the second sleeve.

7. The heat dissipation device of claim 6, wherein several of the plurality of second heat-conducting members corresponding to one of the plurality of first heat-conducting members are arranged along the second direction.

8. The heat dissipation device of claim 1, wherein each of the plurality of second heat-conducting members comprises a thermal interface material, and the thermal interface material is elastic;
the thermal interface material is respectively arranged on opposite two sides of each of the plurality of first heat-conducting members along the first direction.

9. The heat dissipation device of claim 8, wherein each of the plurality of second heat-conducting members further comprises a thermally conducting film;
the thermally conducting film is wrapped on a side of the thermal interface material away from each of the plurality of first heat-conducting members, and each of the slots is between each two adjacent thermally conducting films of the thermally conducting films.

10. The heat dissipation device of claim 8, wherein the thermal interface material is a thermal spacer, a thermally conductive adhesive, a silicone gel, or a silicone grease.

11. A server comprising:
a plurality of memory storages; and
a heat dissipation device, the heat dissipation device comprising:
a plurality of first heat-conducting members arranged at intervals along a first direction;
a plurality of second heat-conducting members arranged at intervals along the first direction, the plurality of second heat-conducting members corresponds to the plurality of first heat-conducting members in an one-to-one relationship, each of the plurality of second heat-conducting members is respectively attached to a corresponding first heat-conducting member of the plurality of first heat-conducting members, along opposite two sides of the corresponding first heat-conducting member in the first direction, slots are defined between each of two of the plurality of second heat-conducting members along the first direction, each of the slots is configured for mounting a memory storage of the plurality of memory storages of the server, each of the plurality of second heat-conducting members is elastic deformable along the first direction, so that each of the slots squeezes a corresponding memory storage and the plurality of second heat-conducting members is closely in contact with the corresponding memory storage; and,
two liquid cooling members respectively located at and connected to two ends of the plurality of first heat-conducting members along a second direction, the liquid cooling members are provided with a flow channel configured for accommodating a cooling medium, wherein the second direction is perpendicular to the first direction;
wherein heat generated by the plurality of memory storages is transferred to the two liquid cooling members and the cooling medium at the two ends of the plurality of first heat-conducting members.

12. The server of claim 11, wherein each of the plurality of second heat-conducting members further comprises a first metal spring tab and a second metal spring tab, the first metal spring tab and the second metal spring tab are located, along the first direction, on respective sides of the corresponding first heat-conducting members;
the first metal spring tab comprises a first contacting portion and a first connecting portion, the first connecting portion is bent and connected to an end of the first contacting portion along a third direction, and the first connecting portion is opposite to the first contacting portion along the first direction, the first connecting portion is located at an side of the first contacting portion close to the corresponding first heat-conducting member, the third direction is perpendicular to the first direction and the second direction respectively;
the second metal spring tab comprises a second contacting portion and a second connecting portion, the second connecting portion is bent and connected to an end of the second contacting portion along the third direction, the second connecting portion is opposite to the second contacting portion along the first direction, and the second connecting portion is located at an side of the second contacting portion close to the corresponding first heat-conducting member;
each of the plurality of first heat-conducting members is connected between the first connecting portion and the second connecting portion near to the first connecting portion;
each of the slots is defined between the first contacting portion and the second contacting portion near the first connecting portion.

13. The server of claim 12, wherein each of the plurality of second heat-conducting members comprises a top side and a bottom side opposite to the top side along the third direction;
the first connecting portion is bent and connected to an end of the first contacting portion along the third direction close to the bottom side;
the second connecting portion is bent and connected to an end of the second contacting portion along the third direction close to the top side.

14. The server of claim 12, wherein the first contacting portion is provided with a first sleeve, and an axial direction of the first sleeve is parallel to the third direction;
the second contacting portion is provided with a second sleeve, the second sleeve corresponds to the first sleeve, and an axial direction of the second sleeve is parallel to the third direction;
the heat dissipation device further comprises a constraining member, the constraining member corresponds to the first sleeve and the second sleeve respectively, and the constraining member is movably mounted to the first sleeve and the second sleeve along the third direction, so that the first contacting portion is closed towards the first connecting portion, and the second contacting portion is closed toward the second connecting portion.

15. The server of claim 14, wherein the second sleeve and the first sleeve are spaced apart from each other along the first direction;
the constraining member comprises a bending portion, a first plunger and a second plunger;
an end of the first plunger is connected with an end of the bending portion, the first plunger extends along the third direction, and the first plunger is movably mounted to the first sleeve along the third direction;
an end of the second plunger is connected with an end of the bending portion away from the first plunger, the second plunger extends along the third direction, the second plunger is spaced from the first plunger along the first direction, and the second plunger is movably mounted to the second sleeve along the third direction.

16. The server of claim 15, wherein two ends along the second direction of the first contacting portion are respectively provided with the first sleeve;
two ends along the second direction of the second contacting portion are respectively provided with the second sleeve.

17. The server of claim 16, wherein several of the plurality of second heat-conducting members corresponding to one of the plurality of first heat-conducting members are arranged along the second direction.

18. The server of claim 11, wherein each of the plurality of second heat-conducting members comprises a thermal interface material, and the thermal interface material is elastic;
the thermal interface material is respectively arranged on opposite two sides of each of the plurality of first heat-conducting members along the first direction.

19. The server of claim 18, wherein each of the plurality of second heat-conducting members further comprises a thermally conducting film;
the thermally conducting film is wrapped on a side of the thermal interface material away from each of the plurality of first heat-conducting members, and each of the slots is between each two adjacent thermally conducting films of the thermally conducting films.

20. The server of claim 18, wherein the thermal interface material is a thermal spacer, a thermally conductive adhesive, a silicone gel, or a silicone grease.
